(19) United States
(12) Patent Application Publication
(10) Pub. No.: US 2017/0092574 A1
(43) Pub. Date: Mar. 30, 2017

(54) METHOD FOR MANUFACTURE A POWER ELECTRONIC SWITCHING DEVICE AND POWER ELECTRONIC SWITCHING DEVICE

(71) Applicant: Semikron Elektronik GmbH & Co., KG, Nurnberg (DE)

(72) Inventors: Florian WAGNER, Nurnberg (DE); Hartmut Kulas, Heroldsberg (DE)

(73) Assignee: Semikron Elektronik GmbH & Co., KG, Nurnberg (DE)

(21) Appl. No.: 15/276,623

(22) Filed: Sep. 26, 2016

(30) Foreign Application Priority Data
Sep. 24, 2015 (DE) 10 2015 116 165.6

(51) Int. Cl. H01L 23/498; H01L 23/29; H01L 21/56; H01L 23/31; H01L 23/00

(52) U.S. Cl. CPC H01L 23/49838; H01L 23/3121; H01L 24/84; H01L 24/40; H01L 21/56; H01L 23/293; H01L 2924/07025; H01L 2924/0685; H01L 2224/32225; H01L 2924/13055; H01L 2924/13091; H01L 2924/1203; H01L 25/18

(57) ABSTRACT

A method for producing a power-electronics switching device and a power electronic switching device produced thereby. In the power-electronics switching device, a power semiconductor component is arranged on a first region of a conductor track of a substrate. An insulating film comprising a cutout is then provided, wherein an overlap region of the insulating film, which overlap region is adjacent to the cutout, is designed to cover an edge region of the power semiconductor component. This is followed by arranging the insulating film on the substrate, with the power semiconductor component arranged on it, in such a way that the power semiconductor component is covered on all sides of its edge region by the covering region of the insulating film, wherein a further section of the insulating film covers parts of one of the conductor tracks. Finally, the connecting device is arranged.

### BACKGROUND OF THE INVENTION

1. Field of the Invention

The invention is directed to a method for producing a power-electronics switching device and a power-electronics switching device which is produced in accordance with this method. A power-electronics switching device of this kind can form the base cell of a power semiconductor module or a power-electronics system by, on its own or in combination with further preferably identical base cells, forming the power-electronics basic element of the power semiconductor module or of the power-electronics system.

2. Description of the Related Art

The prior art is formed, by way of example, by DE 10 2007 006 706 A1. This document discloses a method for producing a power-electronics switching device, the method comprising the steps of:
Forming a plurality of sintered metal areas on conductor tracks of the substrate.
Arranging at least one semiconductor component on an associated sintered metal area.
Arranging the insulating material on the side surface of the semiconductor component. In particular, injection-molding or casting processes, which are followed by cross-linking, by way of example, by UV exposure, are advantageous here.
Arranging the connecting device.
Pressure sintering connection of the connecting device and of the semiconductor component.

As is routine in the art, a power-electronics switching device, which is produced in this way, for inner insulation, in particular for complying with relevant standards such as EN 60664 or IEC 60664, also has to be encapsulated with an encapsulation material, as is known, by way of example, from DE 10 2007 044 620 A1 or DE 10 2009 000 888 A1.

### SUMMARY OF THE INVENTION

It is an object of the invention is to provide an improved power-electronics switching device and a method for its manufacture.

It is therefore an object of the invention to provide a method for producing a power-electronics switching device and an arrangement, wherein the inner insulation of the switching device can be produced more easily.

The method according to the invention for producing a power-electronics switching device comprising a substrate, a power semiconductor component, which is arranged on the substrate, and a planar connecting device, which together form the connection partners of the power-electronics switching device. The method comprises the following steps, in particular in the given order, of:

a) providing the substrate comprising first conductor tracks which are electrically insulated from one another, the power semiconductor component and the connecting device;
b) arranging the power semiconductor component on an associated conductor track of the substrate;
c) providing an insulating film comprising a cutout, wherein an overlap region of the insulating film, which overlap region is adjacent to the cutout, is positioned to cover an edge region of the power semiconductor component;
d) arranging the insulating film in a planar manner on the substrate, with the power semiconductor component arranged thereon, so that the power semiconductor component is covered on all sides of its edge region by a covering region of the insulating film, wherein a central region of the power semiconductor component remains uncovered owing to the cutout, and wherein a further section of the insulating film covers parts of one of the conductor tracks; furthermore, parts of the substrate which are not covered by a conductor track, in particular an insulating body, can be covered by the insulating film; here, it may be advantageous when the central region of the power semiconductor component is completely cleared owing to the cutout with the edge region of the power semiconductor component being covered by the covering region; similarly, it may be advantageous when the insulating film has a further cutout in the region of one of the conductor tracks; and
e) arranging the connecting device.

It goes without saying that, if this is not precluded per se, the features cited in the singular can be provided twice or more in the switching device according to the invention. By way of example, the power semiconductor component may be at least one power semiconductor component, wherein this can likewise be understood to mean that a plurality of power semiconductor components are arranged on one or more conductor tracks of the substrate.

It is especially advantageous when the insulating film has a thickness of between about 50 μm and about 800 μm, in particular of between about 150 μm and about 400 μm, and has a dielectric strength of more than about 500 kV/m, in particular of more than about 2000 kV/m, and a specific resistance of more than about 10⁹ Ω/m, in particular of more than about 10¹⁰ Ω/m.

To this end, it is advantageous when the insulating film is composed of polyimide—PI or of polyether ether ketone—PEEK or of liquid crystal polymer—LCP.

The cutout in the insulating film is preferably produced by a cutting plotter or by a laser cutting device.

It is also particularly preferred when the insulating film has an adhesive layer on its surface which faces the substrate, in particular over the entire surface area, and is adhesively fastened to the edge region of the power semiconductor component and to the section of the conductor track by the adhesive layer.

It is further advantageous when a connector is arranged between in each case two connection partners, the connector being suitable for forming a cohesive connection, preferably a pressure sintering connection, between associated contact areas of the connection partners. To this end, the connector can be arranged in platelet form or as a suspension.

The following method step of:

f) subjecting the power-electronics switching device to a temperature of 110° C. to 400° C. and a pressure of 5 MPa to 50 MPa, wherein at least two connection partners are connected to one another in a cohesive manner at the same time,

is advantageously performed following method step e).

In particular, the connecting device can be designed as a film/foil stack which is formed by an alternating arrangement of at least one electrically conductive foil and at least one electrically insulating film. By way of example, a film/foil stack comprising a first electrically conductive foil, an insulating film and a second electrically conductive foil is preferred. The electrically conductive foils are preferably inherently structured to form further conductor tracks. The film/foil stack preferably has plated-through holes through the insulating film from the first electrically conductive foil to the second electrically conductive foil at the necessary points. Therefore, complex electrical connection topologies can be produced.

The power-electronics switching device according to the invention, in particular produced in accordance with the above-described method, is designed with a substrate, a power semiconductor component which is arranged on the substrate, and a planar connecting device, wherein these connection partners are electrically conductively connected to one another in a cohesive manner suitable for the circuit, and wherein the power semiconductor component is covered on all sides of its edge region by a covering region of the insulating film.

The power-electronics switching device preferably has a load connection device and optionally also an auxiliary connection device which is in each case connected in a force-fitting or cohesive manner to a conductor track or to an electrically conductive foil of the connecting device.

It goes without saying that the different refinements of the invention can be realized individually or in any desired combinations which are not mutually exclusive per se, to achieve improvements. In particular, the features mentioned and explained above and below, irrespective of whether they are mentioned in the context of the method or the object, can be used not only in the combinations indicated, but also in other combinations or by themselves, without departing from the scope of the present invention.

Other objects and features of the present invention will become apparent from the following detailed description of the presently preferred embodiments, considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings:

FIG. 1 shows an exploded lateral sectional view of a first power-electronics switching device, which is produced according to the invention, in a first plane;

FIG. 2 shows a lateral sectional view of a first power-electronics switching device, which is produced according to the invention, in a second plane;

FIG. 3 shows a detail of the first switching device;

FIG. 4 shows a detail of a second switching device which is produced according to the invention;

FIG. 5 shows a further detail of the first switching device; and

FIG. 6 shows a plan view of the first switching device which is produced according to the invention.

### DETAILED DESCRIPTION OF THE PRESENTLY PREFERRED EMBODIMENTS

FIG. 1 shows an exploded illustration of a lateral sectional view, cf. section A-A in FIG. 6, of a first power-electronics switching device 1 according to the invention and a cooling device 4 on which power-electronics switching device 1 can be arranged in a manner which is routine in the art. The figure shows a substrate 2, which is formed in a manner which is fundamentally routine in the art, comprising an insulating body 20 and conductor tracks 22 which are arranged on insulating body 20 and are each electrically insulated from one another and have different potentials, in particular load potentials, but also have auxiliary potentials, in particular switching potentials and measuring potentials, of power-electronics switching device 1. The figure specifically shows three conductor tracks 22 with load potentials as are typical of a half-bridge topology.

A power switch 24 is in each case arranged on two conductor tracks 22, power switch 24 being designed in a manner which is routine in the art as an individual switch, for example as a MOS-FET, or as an IGBT with a power diode connected back-to-back in parallel. Power switches 24 are electrically conductively connected to conductor tracks 22 in a manner which is routine in the art, preferably by a pressure sintering connection.

The internal connections of power-electronics switching device 1 are formed by a connecting device 3 comprising a film/foil stack which has alternating electrically conductive foils 30, 34 and electrically insulating films 32. In this case, the film/foil stack has precisely two conductive foils and an insulating film which is arranged between the conductive foils. In particular, the conductive foils 30, 34 of the connecting device 3 are inherently structured and therefore form further conductor tracks which are electrically insulated from one another. These further conductor tracks connect, in particular, the respective power semiconductor component 24, more precisely the contact areas of power semiconductor component 24 on that side which is averted from substrate 2, to conductor tracks 22 of substrate 2. In a preferred refinement, the respective further conductor tracks are connected to the associated contact areas in a cohesive manner by a sintered connection. It goes without saying that connections between different power semiconductor components 24 and also between different conductor tracks 22 of substrate 2 can also be formed in the same way.

According to the invention, an insulating film 5 is adhesively connected to substrate 2, and therefore also to conductor tracks 22 of substrate, and likewise adhesively connected to the respective edge region 242 of power semiconductor components 24. Here, insulating film 5 has cutouts 540 which have been produced by laser cutting methods. Therefore, in the arranged state, a covering region 54 of insulating film 5 runs around on edge region 242 of the respective power semiconductor component 24. In this context, “runs around” is intended to be understood to mean that substantially the entire edge region 242 of power semiconductor component 24 is covered by overlap region 54 of insulating film 5 on all sides, that is to say without interruption, also cf. FIG. 6.

For the purpose of electrical connection, power-electronics switching device 1 has load connection elements 26 and auxiliary connection elements 28. Load connection elements 26 are designed, purely by way of example, as shaped metal bodies which are connected by way of a contact foot to a conductor track 22 of substrate 2 in a cohesive manner, advantageously likewise by a sintered connection or else by a soldered connection. In principle, parts of connecting device 3 themselves can also be designed as load connection elements or auxiliary connection elements. Auxiliary connection elements 28, such as gate connections or sensor connections, can moreover be designed in a manner which is routine in the art, as shown in the form of spring contacts.

Power-electronics switching device 1 is arranged on a cooling device 4 in a manner which is routine in the art, and can be thermally conductively connected to cooling device 4, by way of example, by an adhesive, soldered or sintered connection. As an alternative, power-electronics switching device 1 can be arranged on cooling device 4 and thermally conductively connected to cooling device 4 by a pressure contact device and a thermally conductive intermediate layer 40. In this way, the power loss from power semiconductor component 24 can be efficiently dissipated.

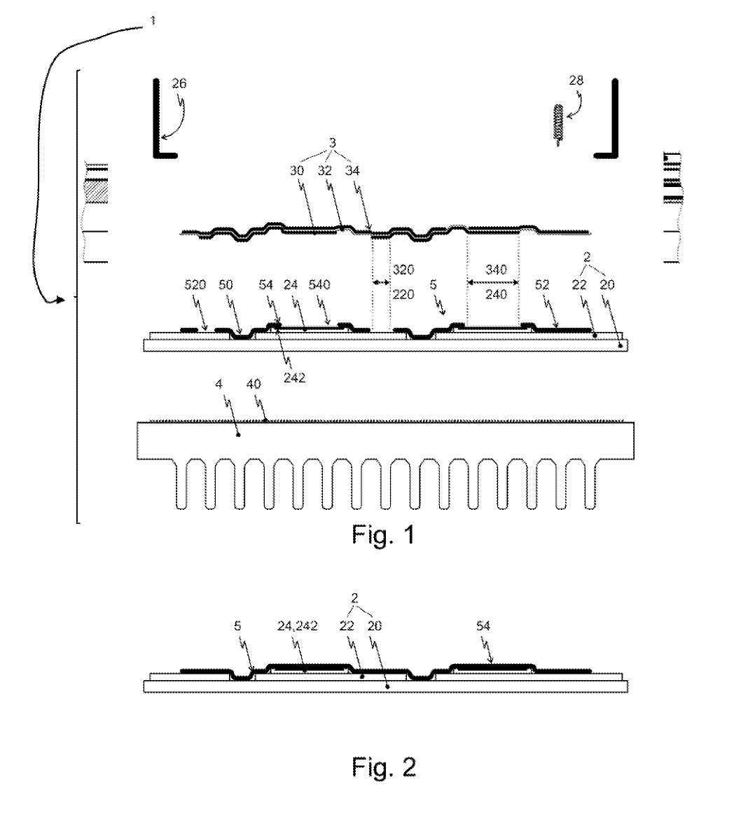

FIG. 2 shows a lateral side view, cf. section B-B in FIG. 6, of the first power-electronics switching device 1 according to the invention. The figure once again shows substrate 2 comprising an insulating body 20 and conductor tracks 22 which are arranged on insulating body 20. Power semiconductor components 24 are arranged on conductor tracks 22. The figure likewise shows insulating film 5. This sectional view shows edge region 242 of power semiconductor components 24, as a result of which insulating film 5 is illustrated in a continuous form, that is to say with its overlap region 54 in complete form along power semiconductor component 24.

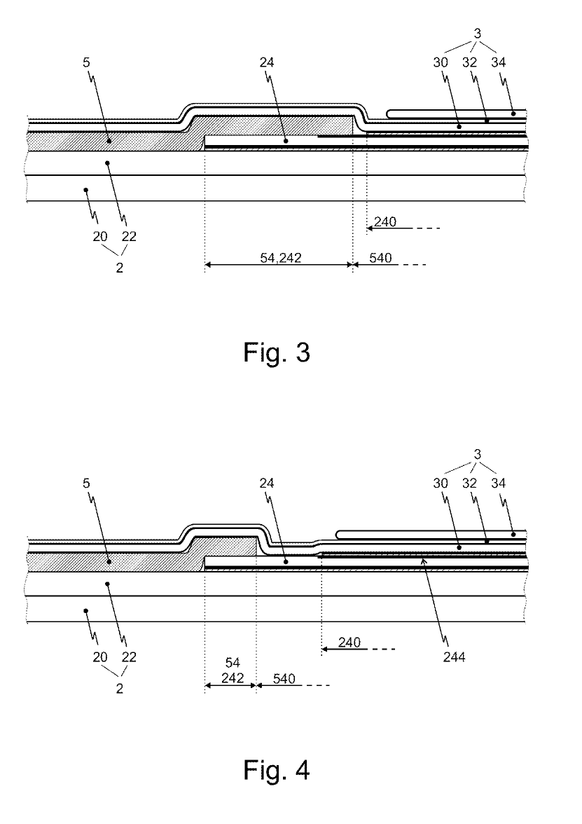

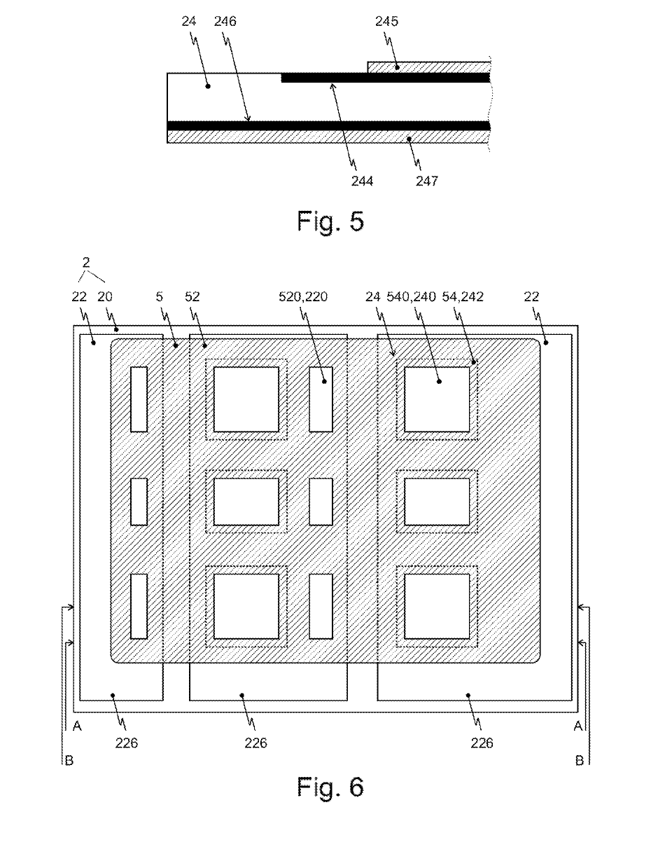

FIG. 3 shows a detail of the first switching device. The figure shows, on an enlarged scale in comparison to FIG. 1, a conductor track 22 with a power semiconductor component 24, in this case an IGBT of voltage class 1200 V, which is only partially illustrated. Power semiconductor component 24, more precisely a first contact area 246 of power semiconductor component 24, which first contact area 246 faces substrate 2, is arranged on and connected in an electrically conductive and cohesive manner to, conductor track 22 by a pressure sintering connection by way of a first connector 247, respectively cf. FIG. 5.

FIG. 3 further shows a second contact area 244 of power semiconductor component 24, likewise cf. FIG. 5, which second contact area 244 is averted from substrate 2 and does not extend as far as the edge of power semiconductor component 24. As is routine in the art, an edge structure, in particular a field ring structure, is formed between second contact area 244 and the edge of power semiconductor component 24; however, the edge structure is not shown.

FIG. 3 further shows insulating film 5 which, by way of its covering region 54, covers edge region 242 of power semiconductor component 24 and is adhesively connected to power semiconductor component 24 there. In this case, this covering region 54 extends over the edge of second contact area 244 of power semiconductor component 24. Insulation from conductor track 22, which is required according to standard, is ensured by this refinement.

In some places, this edge region 242 of power semiconductor component 24 is sensitive to environmental moisture during operation of the switching device. A further advantage is achieved owing to the arrangement of insulating film 5 according to this refinement, specifically that of covering edge region 242 of power semiconductor component 24 in a moisture-tight manner and therefore of reliable operation of the switching device even under environmental conditions involving a high level of atmospheric humidity.

In principle, it is preferred when the entire surface of insulating film 5, which surface faces substrate 2, is adhesive, as a result of which it adheres to conductor tracks 22 and also to insulating body 20 between conductor tracks 22.

In this case, insulating film 5 itself is composed of polyimide and has a thickness of approximately 500 μm. This produces a dielectric strength of more than 800 kV/m.

FIG. 3 likewise shows connecting device 3, first electrically conductive foil 30 of connecting device 3, more precisely a contact section 320 of electrically conductive foil 30, being connected to second contact area 244 of power semiconductor component 24 by a pressure sintering connection by way of a connector 245, respectively cf. FIG. 5. This first electrically conductive foil 30 or the further conductor track which is formed from it, serves, cf. FIG. 1, to electrically connect second contact area 244 of power semiconductor component 24 to conductor track 22 of substrate 2, which conductor track 22 is arranged next to second contact area 244.

Insulating film 32 is arranged on that side of first electrically conductive foil 30 which is averted from substrate 2, and the second electrically conductive foil 34 is, in turn, arranged on insulating film 32. On account of its structuring, this second electrically conductive foil 34 extends only as far as above second contact area 244 of power semiconductor component 24.

FIG. 4 shows a detail of a second switching device which is produced according to the invention. In contrast to the refinement according to FIG. 3, overlap section 54 of insulating film 5 does not overlap edge region 242 of power semiconductor component 24 as far as second contact area 244 of power semiconductor component 24.

FIG. 5 shows a further detail of the first switching device. The figure shows power semiconductor component 24 comprising a silicon body having first and second contact areas 244, 246. Connector 245, 247 of the pressure sintering connection are shown on these contact areas 244, 246, the connector, in particular in the case of second contact area 244, not extending as far as the edge of second contact area 246.

FIG. 6 shows a plan view of the first switching device which is produced according to the invention. The figure shows a substrate 2 comprising an insulating body 20, here, without restricting the generality of the disclosure, an industrial ceramic such as aluminum oxide or aluminum nitride. Three conductor tracks 22 for load potentials are shown on insulating body 20. Conductor tracks for auxiliary potentials, which conductor tracks are routine in the art, have not been shown.

In each case two power transistors 24, in this case IGBTs, and one power diode, arranged between the two IGBTs, are shown on two of the three conductor tracks 22. Power semiconductor components 24 usually have edge lengths of about 0.5 cm to about 1.5 cm.

FIG. 6 also shows insulating film 5 with in each case one cutout 540 for each power semiconductor component 24. This cutout 540 is designed in the manner described above and has an overlap region 54 with power semiconductor component 24 on all sides, wherein this covering region 54, also cf. FIGS. 3 and 4, has a width of about 0.25 mm to about 2 mm, in particular of about 0.8 mm to about 1.5 mm. A central region of power semiconductor component 24, which is completely cleared, remains owing to edge region 242 of power semiconductor component 24 being covered by covering region 54. These cutouts 540 in insulating film 5 are produced by a laser cutting device here.

Insulating film 5 further covers the region of conductor tracks 22 around the respective power semiconductor component 24 and partially also the intermediate regions between adjacent conductor tracks 22, also cf. FIGS. 1 and 2.

Furthermore, insulating film 5 has further cutouts 520 in two of the three conductor tracks 22, the further cutouts serving to connect second contact areas 244 of power semiconductor component 24 to these conductor tracks 22 by a further conductor track of an electrically conductive foil 30 of connecting device 3.

In the preceding Detailed Description, reference was made to the accompanying drawings, which form a part of this disclosure, and in which are shown illustrative specific embodiments of the invention. In this regard, directional terminology, such as “top”, “bottom”, “left”, “right”, “front”, “back”, etc., is used with reference to the orientation of the Figure(s) with which such terms are used. Because components of embodiments can be positioned in a number of different orientations, the directional terminology is used for purposes of ease of understanding and illustration only and is not to be considered limiting.

Additionally, while there have been shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A method for producing a power-electronics switching device which comprises a substrate, a power semiconductor component having an edge region arranged on the substrate, and a planar connecting device, which form the connection partners of the power-electronics switching device, the method comprising the steps of:
a) providing the substrate with first conductor tracks which are electrically insulated from one another, the power semiconductor component and the connecting device;
b) arranging the power semiconductor component on one of said first conductor tracks;
c) providing a first insulating film which includes a cutout;
d) arranging said first insulating film in a planar manner on the substrate, with the power semiconductor component arranged thereon, so that the power semiconductor component is covered on all sides of its edge region by a covering region of said first insulating film, wherein a central region of the power semiconductor component remains uncovered due to the presence of said cutout, and wherein a further section of said first insulating film covers parts of the conductor tracks; and
e) arranging the connecting device.

2. The method of claim 1, wherein said central region of the power semiconductor component is completely cleared with the edge region of the power semiconductor component being covered by said covering region.

3. The method of claim 1, wherein said first insulating film has a thickness of between about 50 μm and about 800 μm, has a dielectric strength of more than about 500 kV/m, and has a specific resistance of more than about 10⁹ Ω/m.

4. The method of claim 3, wherein said first insulating film has a thickness of between about 150 μm and about 400 μm.

5. The method of claim 3, wherein said first insulating film has a dielectric strength of more than about 2000 kV/m.

6. The method of claim 3, wherein said first insulating film has a specific resistance of more than about 10¹⁰ Ω/m.

7. The method of claim 1, wherein said first insulating film is composed of one of the group consisting of polyimide—PI, polyether ether ketone—PEEK and liquid crystal polymer—LCP.

8. The method of claim 1, wherein said first insulating film has a further cutout in the region of one of said conductor tracks.

9. The method of claim 1, further comprising the step of arranging a connector between two of the connection partners, said connector being suitable for forming a cohesive connection between associated contact areas of the connection partners so joined.

10. The method of claim 9, wherein said connector is arranged as one of in platelet form and as a suspension.

11. The method of claim 9, further comprising the step of:
f) heating the power-electronics switching device to a temperature of from about 110° C. to about 400° C. and at a pressure of from about 5 MPa to about 50 MPa;
wherein at least two of the connection partners are connected to one another in a cohesive manner at the same time; and
wherein said step f) is performed following step e).

12. The method of claim 1, wherein the planar connecting device is formed as a film/foil stack which is formed by an alternating arrangement of at least one electrically conductive foil, which forms second conductor tracks, and at least one second electrically insulating film.

13. The method of claim 1, wherein said cutout is produced by one of a cutting plotter and a laser cutting device.

14. The method of claim 1, further comprising the step of adhesively attaching said first insulating film to the edge region of the power semiconductor component and to one of said first conductor tracks by an adhesive layer, said adhesive layer being disposed on the surface of said first insulating film which faces the substrate.

15. A power-electronics switching device comprising:
a substrate having first conductor tracks;
a power semiconductor component having an edge region and a central region, said power semiconductor being arranged on one of said first conductor tracks;
a planar connecting device; and
an insulating film having a covering region which covers all sides of said edge region of said power semiconductor component and also having a cutout, said first insulating film being arranged in a planar manner on said substrate, with said power semiconductor component arranged thereon, so that the power semiconductor component is covered on all sides of its edge region by said covering region of said first insulating film, while said central region of said power semiconductor component remains uncovered due to the positioning of said cutout, said first insulating film also covering parts of said first conductor tracks
wherein said first conductor are electrically insulated from one another, the power semiconductor component and the connecting device; and
wherein said substrate, said power semiconductor component and said planar connecting device are electrically conductively connected to one another in a cohesive manner suitable for the circuit.

16. The power-electronics switching device of claim 15, further comprising a load connection device connected to one of one of said first conductor tracks and an electrically conductive foil of said planar connecting device in one of a force-fitting and cohesive manner.

17. The power-electronics switching device of claim 15, further comprising an auxiliary connection device connected in one of a force-fitting and cohesive manner to one of one of said first conductor tracks and an electrically conductive foil of said planar connecting device.

18. The power switching device of claim 15, wherein the power switching device is produced by the method of claim 1.
